(19) United States
(12) Patent Application Publication
(10) Pub. No.: US 2017/0031246 A1
(43) Pub. Date: Feb. 2, 2017

(54) Inspection Apparatus, Inspection Method and Manufacturing Method

(71) Applicant: ASML Netherlands B.V., Veldhoven (NL)

(72) Inventor: Arie Jeffrey DEN BOEF, Waalre (NL)

(73) Assignee: ASML Netherlands B.V., Veldhoven (NL)

(21) Appl. No.: 15/216,998

(22) Filed: Jul. 22, 2016

(30) Foreign Application Priority Data
Jul. 30, 2015 (EP) 15179154.8

(51) Int. Cl. G03F 7/20; G01B 11/27; G01N 21/47

(52) U.S. Cl. CPC G03F 7/70133; G01N 21/4788; G01B 11/272; G01N 2201/06113

(57) ABSTRACT

An inspection apparatus is provided for measuring properties of a non-periodic product structure (500′). A radiation source (402) and an image detector (408) provide a spot (S) of radiation on the product structure. The radiation is spatially coherent and has a wavelength less than 50 nm, for example in the range 12-16 nm or 1-2 nm. The image detector is arranged to capture at least one diffraction pattern (606) formed by said radiation after scattering by the product structure. A processor receives the captured pattern and also reference data (612) describing assumed structural features of the product structure. The process uses coherent diffraction imaging (614) to calculate a 3-D image of the structure using the captured diffraction pattern(s) and the reference data. The coherent diffraction imaging may be for example ankylography or ptychography. The calculated image deviates from the nominal structure, and reveals properties such as CD, overlay.

### BACKGROUND

Field of the Invention

The present invention relates to inspection apparatus and methods usable, for example, to perform metrology in the manufacture of devices by lithographic techniques. The invention further relates to an illumination system for use in such inspection apparatus and to methods of manufacturing devices using lithographic techniques. The invention yet further relates to computer program products for use in implementing such methods.

Background Art

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

In lithographic processes, it is desirable frequently to make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device. Recently, various forms of scatterometers have been developed for use in the lithographic field.

Examples of known scatterometers often rely on provision of dedicated metrology targets. For example, a method may require a target in the form of a simple grating that is large enough that a measurement beam generates a spot that is smaller than the grating (i.e., the grating is underfilled). In so-called reconstruction methods, properties of the grating can be calculated by simulating interaction of scattered radiation with a mathematical model of the target structure. Parameters of the model are adjusted until the simulated interaction produces a diffraction pattern similar to that observed from the real target.

In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. These targets can be smaller than the illumination spot and may be surrounded by product structures on a wafer. Examples of dark field imaging metrology can be found in numerous published patent applications, such as for example US2011102753A1 and US20120044470A. Multiple gratings can be measured in one image, using a composite grating target. The known scatterometers tend to use light in the visible or near-IR wave range, which requires the grating to be much coarser than the actual product structures whose properties are actually of interest. Such product features may be defined using deep ultraviolet (DUV) or extreme ultraviolet (EUV) radiation having far shorter wavelengths. Unfortunately, such wavelengths are not normally available or usable for metrology. Product structures made for example of amorphous carbon may be opaque to radiation of shorter wavelength.

On the other hand, the dimensions of modern product structures are so small that they cannot be imaged by optical metrology techniques. Small features include for example those formed by multiple patterning processes, and/or pitch-multiplication. Hence, targets used for high-volume metrology often use features that are much larger than the products whose overlay errors or critical dimensions are the property of interest. The measurement results are only indirectly related to the dimensions of the real product structures, and may be inaccurate because the metrology target does not suffer the same distortions under optical projection in the lithographic apparatus, and/or different processing in other steps of the manufacturing process. While scanning electron microscopy (SEM) is able to resolve these modern product structures directly, SEM is much more time consuming than optical measurements. Other techniques, such as measuring electrical properties using contact pads is also known, but it provides only indirect evidence of the true product structure.

The inventor has considered whether the techniques of coherent diffraction imaging (CDI), combined with radiation of wavelength comparable with the product structures of interest, might be applied to measure properties of device structures. CDI is also known as lensless imaging, because there is no need for physical lenses or mirrors to focus an image of an object. The desired image is calculated synthetically from a captured light field. A particular example of CDI is known as ankylography, which offers the potential to determine properties of a 3-D structure from a single capture. In order to do this, an image of a radiation field is obtained, that has been diffracted by an object, for example a microstructure made by lithography. Different types of prior information are considered in the literature, which allow phase information to be retrieved, so that the object can be reconstructed, even though the radiation field is only captured in intensity (revealing the magnitude but not the phase of the radiation field). Literature describing ankylography at EUV wavelengths includes: the paper “Designing and using prior data in Ankylography: Recovering a 3D object from a single diffraction intensity pattern” E. Osherovich et al http://arxiv.org/abs/1203.4757 and the PhD thesis by E. Osherovich “Numerical methods for phase retrieval”, Technion, Israel—Computer Science Department—Ph.D. Thesis PHD-2012-04-2012). Other approaches are described in a Letter by by K S Raines et al “Ankylography: Three-Dimensional Structure Determination from a Single View”, published in Nature 463, 214-217 (14 Jan. 2010), doi:10.1038/nature08705 and in a related presentation by Jianwei (John) Miao, KITP Conference on X-ray Science in the 21st Century, UCSB, 2-6 Aug. 2010 (available at http://online.kitp.ucsb.edu/online/atomixrays-c10/miao/). Another PhD thesis describing lensless imaging at EUV wavelengths is “High-Resolution Extreme Ultraviolet Microscopy” by M. W. arch, Springer Theses, DOT 10.1007/978-3-319-12388-2_1. Another example of CDI is ptychography, described for example in published patent application US 2010241396 and U.S. Pat. Nos. 7,792,246, 8,908,910, 8,917,393, 8,942,449, 9,029,745 of the company Phase Focus Limited and the University of Sheffield. In ptychography, phase information is retrieved from a plurality of captured images with an illumination filed that is moved slightly between successive captures. Overlap between the illumination fields allows reconstruction of phase information and 3-D images. Other types of CDI can be considered also.

Unfortunately, the types of constraints (prior knowledge) exploited in the literature cannot readily be applied to the product structures of interest.

### SUMMARY OF THE INVENTION

The present invention aims to provide an alternative inspection apparatus and method for performing measurements of the type described above.

According to a first aspect of the present invention, there is provided an inspection apparatus for measuring properties of a product structure, the apparatus comprising a radiation source and an image detector in combination with an illumination optical system, wherein the radiation source and the illumination optical system are arranged to provide a spot of radiation on the product structure, the radiation having a wavelength less than 50 nm, and wherein the image detector is arranged to capture at least one diffraction pattern formed by said radiation after scattering by the product structure, and wherein the inspection apparatus further comprises a processor arranged (i) to receive image data representing said captured diffraction pattern, (ii) to receive reference data describing assumed structural features of the product structure and (iii) to calculate from the image data and the reference data one or more properties of the product structure.

Such an apparatus can be used to perform so-called “lensless” imaging. This avoids the difficulties associated with providing imaging optics for the shorter wavelengths. The image obtained and used to measure properties of the structure may be called a “synthetic image” because it never existed in the physical world: it exists only as data and is obtained by computation from data representing the scattered radiation field.

The inventor has determined that coherent diffraction imaging techniques can be applied to the inspection of complex, extensive device structures, using a different type of prior knowledge in a different way. In embodiments of the present invention, prior knowledge of a nominal structure is used, representing for example a product structure as designed. Using this prior knowledge together with a captured image of radiation diffracted by the real structure, CDI techniques such as ankylography or ptychography can be performed to reconstruct deviations from the nominal structure. Where the nominal structure is for example the device structure ‘as designed’, the reconstructed deviations can represent directly parameters of interest, such as CD error and overlay.

The invention further provides a measuring properties of a product structure, the method comprising the steps:

(a) providing a spot of radiation on the product structure, the radiation having a wavelength less than 50 nm;

(b) capturing at least one diffraction pattern formed by said radiation after scattering by the product structure;

(c) receiving reference data describing assumed structural features of the product structure; and

(d) calculating from the image data and the reference data one or more properties of the product structure.

The invention yet further provides a method of manufacturing devices wherein product structures are formed on a series of substrates by a lithographic process, wherein properties of the product structures on one or more processed substrates are measured by a method according to the invention as set forth above, and wherein the measured properties are used to adjust parameters of the lithographic process for the processing of further substrates.

The invention yet further provides a computer program product containing one or more sequences of machine-readable instructions for implementing calculating steps in a method according to the invention as set forth above.

These and other aspects and advantages of the apparatus and methods disclosed herein will be appreciated from a consideration of the following description and drawings of exemplary embodiments.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus;

FIG. 2 depicts a lithographic cell or cluster in which an inspection apparatus according to the present invention may be used;

FIG. 3 illustrates schematically a product structure having a nominal form in periodic areas and non-periodic areas;

FIG. 4 illustrates schematically an inspection apparatus for use in measuring deviations of the product structure of FIG. 3;

FIG. 5 (not to scale) illustrates the mapping of diffraction angles to pixels on a planar detector in the apparatus for FIG. 4;

FIGS. 6(a)-6(d) illustrate steps (a) to (c) in the manufacture of an example non-periodic product structure, and (d) deviations that can arise in a real product structure

FIG. 7 illustrates schematically a method of measuring properties of a target structure according to an embodiment of the invention, using for example the apparatus of FIG. 4; and

FIG. 8 illustrates use of the method of FIG. 7 in controlling a lithographic manufacturing process.

### DETAILED DESCRIPTION OF EXEMPLARY EMBODIMENTS

Before describing embodiments of the invention in detail, it is instructive to present an example environment in which embodiments of the present invention may be implemented.

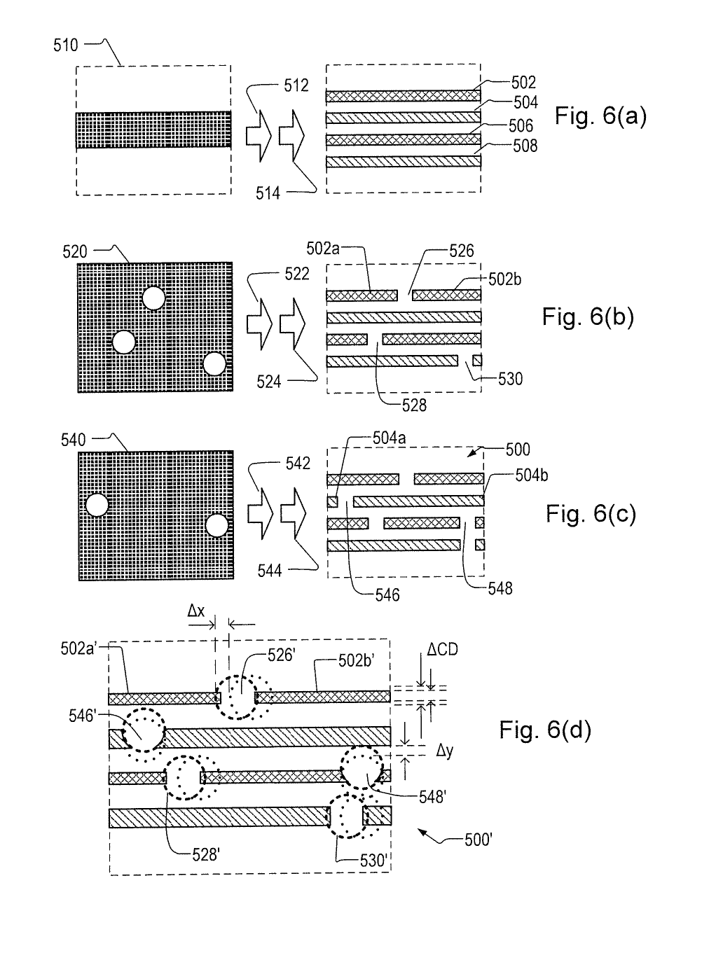

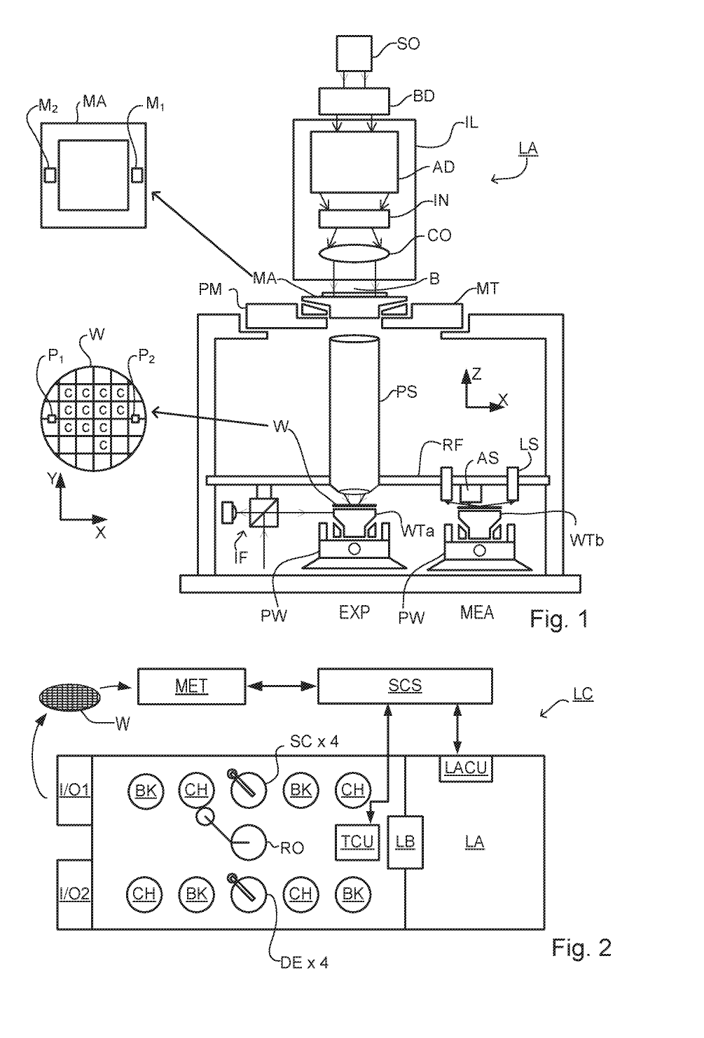

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation. For example, in an apparatus using extreme ultraviolet (EUV) radiation, reflective optical components will normally be used.

The patterning device support holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment mark may also be included within dies, in amongst the device features, in which case it is desirable that the markers be as small as possible and not require any different imaging or process conditions than adjacent features. The alignment system, which detects the alignment markers, is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which lithocell LC is located also includes metrology system MET which receives some or all of the substrates W that have been processed in the lithocell. Metrology results are provided directly or indirectly to the supervisory control system SCS. If errors are detected, adjustments may be made to exposures of subsequent substrates.

Within metrology system MET, an inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it may be desirable that the inspection apparatus measure properties in the exposed resist layer immediately after the exposure. However, not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

The metrology step with metrology system MET can also be done after the resist pattern has been etched into a product layer. The latter possibility limits the possibilities for rework of faulty substrates but may provide additional information about the performance of the manufacturing process as a whole.

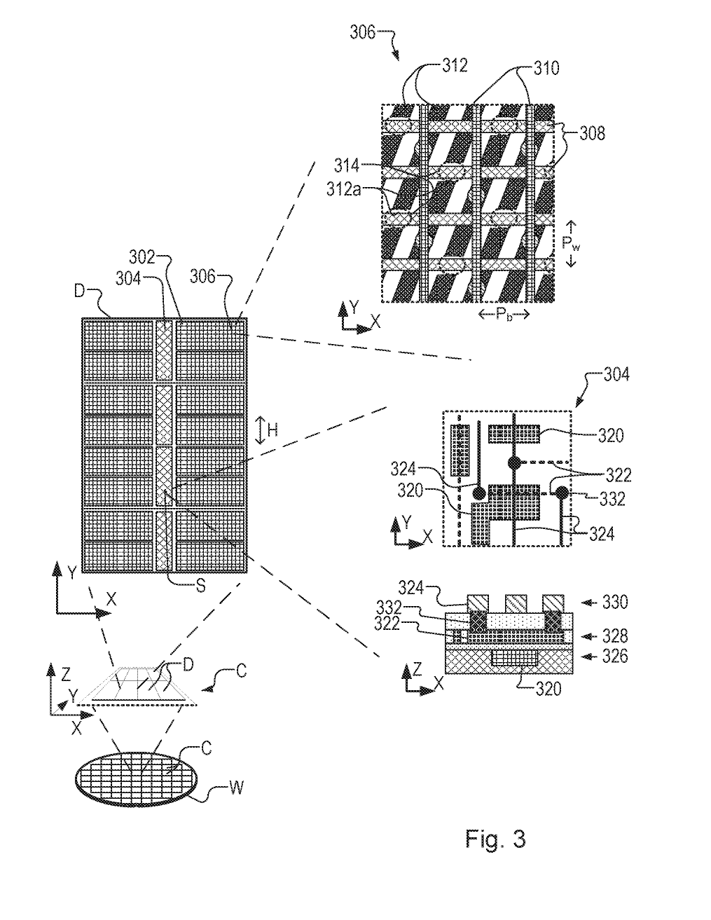

FIG. 3 illustrates characteristics of a product structure that might be subject to measurement by the metrology system MET. It will be assumed that the product structures have been formed by optical lithography , using a system of the type described above with respect to FIGS. 1 and 2. The present disclosure is applicable to measurement of microscopic structures formed by any technique, however, not only optical lithography. A substrate W has product structure formed in target portions C, which may correspond for example to fields of the lithographic apparatus. Within each field a number of device areas D may be defined, each corresponding for example to a separate integrated circuit die.

Within each device area D, product structures formed by lithographic processing are arranged to form functional electronic components. The product illustrated may, for example, comprise a DRAM memory chip. It may have dimension of a few millimeters in each direction. The product comprises a number of memory array areas 302, and a number of logic areas 304. Within the memory array areas 302, sub-areas 306 comprise individual arrays of memory cell structures. Within these sub-areas, the product structures may be periodic. Using known reconstruction techniques, this periodicity can be exploited for measurement purpose. On the other hand, in the logic areas 304, the structure may comprise stub-structures arranged in a non-periodic fashion. Conventional reconstruction techniques are not suited to such structures, and the present disclosure applies lensless imaging particularly to enable metrology in these non-periodic areas.

On the right hand side of FIG. 3, there is shown a small portion of a periodic product structure 306 (plan view only) and a small portion of non-periodic structure 304 (plan and cross-section). Again, the periodic structure could be that of a DRAM memory cell array, but is used only for the sake of example. In the example structure, conductors forming word lines 308 and bit lines 310 extend in X and Y directions throughout the periodic structure. The pitch of the word lines is marked Pw and the pitch of the bit lines is marked Pb. Each of these pitches may be a few tens of nanometers, for example. An array of active areas 312 is formed beneath the word lines and bit lines, with a slanted orientation. The active areas are formed from an array of line features, but cut at locations 312a to be divided longitudinally. The cuts may be made for example by a lithographic step using a cut mask, shown in dotted outline at 314. The process of forming the active areas 312 is thus an example of a multiple patterning process. Bit line contacts 316 are formed at locations to connect each bit line 310 with the active areas 312 below it. The skilled person will appreciate that the different types of features shown in the example product structure are separated in the Z direction, being formed in successive layers during a lithographic manufacturing process.

Also shown on the right hand side in FIG. 3 is a portion of non-periodic product structure 304, which may be part of the logic area of the DRAM product, just by way of example. This structure may comprise for example active areas 320 and conductors 322, 324. The conductors are shown only schematically in the plan view. As can be seen in the cross-section, active areas 320 are formed in a bottom layer 326, conductors 322 are formed in an intermediate layer 328 and conductors 324 are formed in a top layer 330. The term “top layer” refers to the state of manufacturing shown in the diagram, which may or may not be the top layer in a finished product. Contacts 332 are formed to interconnect conductors 322 and 324 at desired points.

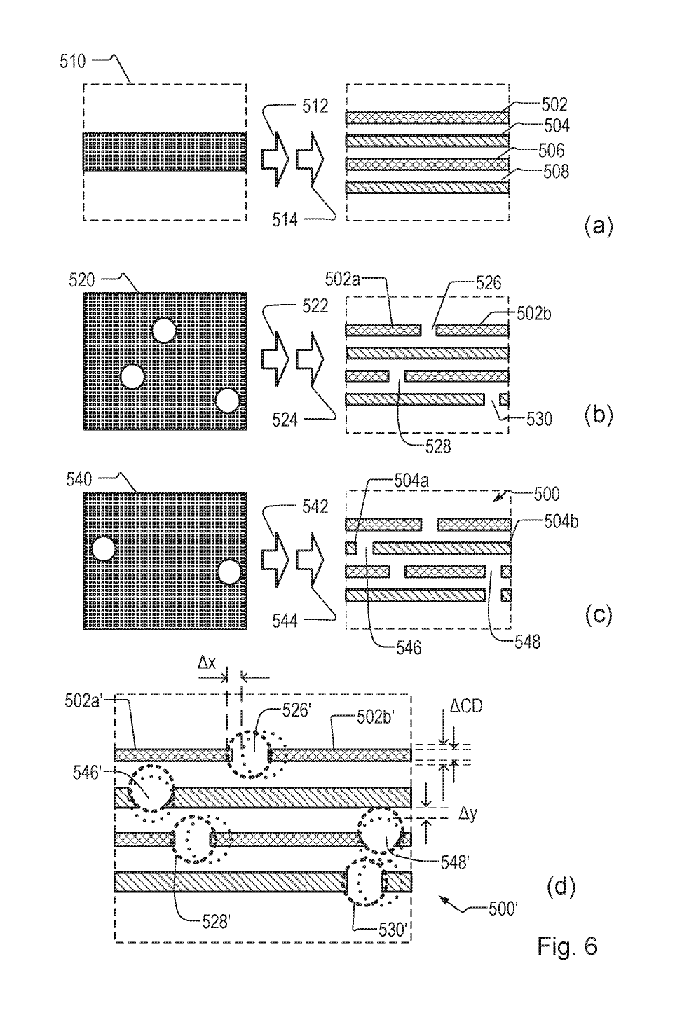

Final performance of manufactured device depends critically on the accuracy of positioning and dimensioning of the various features of the product structure through lithography and other processing steps. While FIG. 3 shows the ideal or nominal product structures 304 and 306, a product structure made by a real, imperfect, lithographic process will produce a slightly different structure. An imperfect product structure will be illustrated below, with reference to FIG. 6.

Overlay error may cause cutting, contact or other modification to occur imperfectly, or in a wrong place. Dimensional (CD) errors may cause cuts be too large, or too small (in an extreme case, cutting a neighboring line by mistake, or failing to cut the intended grid line completely). Performance of devices can be influenced by other parameters of lithographic performance, such as CD uniformity (CDU), line edge roughness (LER) and the like. For reasons mentioned above, it is desirable to perform metrology directly on such structures to determine the performance of the lithographic process for CD, overlay and the like.

For metrology to be performed on a section of product structure in a logic area 304, a spot S of radiation is indicated. The spot diameter may be for example 10 μm or smaller, using the example DRAM structure mentioned above.

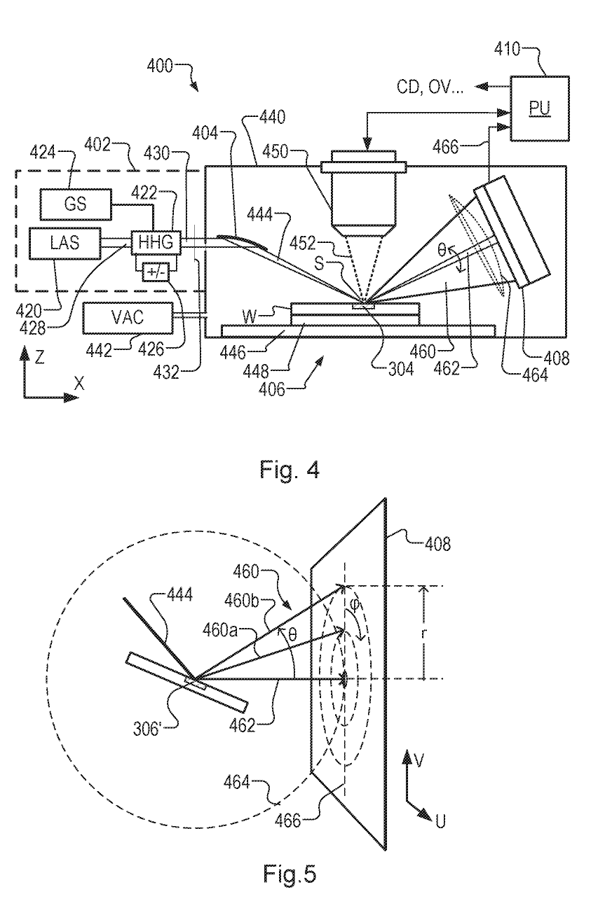

FIG. 4 illustrates in schematic form an inspection apparatus 400 for use in the metrology system MET of FIG. 2. This apparatus is for implementing so-called lensless imaging in wavelengths in the extreme UV (EUV) and soft x-ray (SXR) ranges. For example the radiation used may be at a selected wavelength or wavelengths less than 50 nm, optionally less than 20 nm, or even less than 5 nm or less than 2 nm.

Inspection apparatus 400 comprises an EUV radiation source 402, illumination optical system 404, substrate support 406, detector 408 and processor 410. Source 402 comprises for example a generator of EUV radiation based on high harmonic generation (HHG) techniques. Such sources are available for example from KMLabs, Boulder Colorado, USA (http://www.kmlabs.com/). Main components of the radiation source are a pump laser 420 and an HHG gas cell 422. A gas supply 424 supplies suitable gas to the gas cell, where it is optionally ionized by electric source 426. The pump laser may be for example a fiber-based laser with an optical amplifier, producing pulses of infrared radiation lasting less than 1 ns (1 nanosecond) per pulse, with a pulse repetition rate up to several megahertz, as required. The wavelength may be for example in the region of 1 μm (1 micron). The laser pulses are delivered as a first radiation beam 428 to the HHG gas cell 422, where a portion of the radiation is converted to higher frequencies the first radiation into a beam 430 including coherent radiation of the desired EUV wavelength or wavelengths. The radiation for the purpose of coherent diffraction imaging should be spatially coherent but it may contain multiple wavelengths. If the radiation is also monochromatic the lensless imaging calculations may be simplified, but it is easier with HHG to produce radiation with several wavelengths. These are matters of design choice, and may even be selectable options within the same apparatus. One or more filtering devices 432 may be provided. For example a filter such as a thin membrane of Aluminum (Al) may serve to cut the fundamental IR radiation from passing further into the inspection apparatus. A grating may be provided to select one or more specific harmonic wavelengths from among those generated in the gas cell. Some or all of the beam path may be contained within a vacuum environment, bearing in mind that the desired EUV radiation is absorbed when traveling in air. The various components of radiation source 402 and illumination optics 404 can be adjustable to implement different metrology ‘recipes’ within the same apparatus. For example different wavelengths and/or polarization can be made selectable.

For high-volume manufacturing applications, selection of a suitable source will be guided by cost and hardware size, not only by theoretical ability, and HHG sources are selected as the example here. Other types of sources are also available or under development that may be applied in principle. Examples are synchrotron sources and FEL (free electron laser) sources. T. Depending on the materials of the structure under inspection, different wavelengths may offer a desired level of penetration into lower layers, for imaging of buried structures. For example, wavelengths above 4 or 5 nm may be used. Wavelengths above 12 nm may be used, as these show stronger penetration specifically through silicon material and are available from bright, compact HHG sources. For example, wavelengths in the range 12 to 16 nm may be used. Alternatively or in addition, shorter wavelengths may be used that also exhibit good penetration. For example, wavelengths shorter than 2 nm may be used, as and when a practical source becomes available. Wavelengths in ranges above 0.1 nm and below 50 nm might therefore be considered, including for example the range 1 to 2 nm. The apparatus may be a stand-alone device or incorporated in either the lithographic apparatus LA, or the lithographic cell LC. It can also be integrated in other apparatuses of the lithographic manufacturing facility, such as an etching tool. The apparatus may of course be used in conjunction with other apparatuses such as scatterometers and SEM apparatus, as part of a larger metrology system.

From the radiation source 402, the filtered beam 430 enters an inspection chamber 440 where the substrate W including a product structure is held for inspection by substrate support 406. The product structure is labeled 304, indicating that he apparatus is particularly adapted for metrology on non-periodic structures, such as the logic area 304 of the product shown in FIG. 3. The atmosphere within inspection chamber 440 is maintained near vacuum by vacuum pump 442, so that EUV radiation can pass without undue attenuation through the atmosphere. The Illumination optics 404 has the function of focusing the radiation into a focused beam 444, and may comprise for example a two-dimensionally curved mirror, or a series of one-dimensionally curved mirrors. The focusing is performed to achieve a round spot roughly 10 μm in diameter, when projected onto the product structure. Substrate support 406 comprises for example an X-Y translation stage 446 and a rotation stage 448, by which any part of the substrate W can be brought to the focal point of beam 444 to in a desired orientation. Thus the radiation spot S is formed on the structure of interest. Tilting of the substrate in one or more dimensions may also be provided. To aid the alignment and focusing of the spot S with desired product structures, auxiliary optics 450 uses auxiliary radiation 452 under control of processor.

Detector 408 captured radiation 460 that is scattered by the product structure 306′ over a range of angles θ in two dimensions. A specular ray 462 represents a “straight through” portion of the radiation. This specular ray may optionally be blocked by a stop (not shown), or pass through an aperture in detector 408. In a practical implementation, images with an without the central stop may be taken and combined to obtain a high dynamic range (HDR) image of a diffraction pattern. The range of angles of diffraction can be plotted on a notional sphere 464, known in the art as the Ewald sphere, while the surface of the detector 408 will more conveniently be flat. Detector 408 may be for example a CCD image detector comprising an array of pixels.

FIG. 5 (not to scale) illustrates the mapping of diffraction angles (and consequently points on the Ewald sphere 464) to pixels on a planar detector 408. The dimensions of the pixel array are labeled U, V in a pseudo-perspective representation. The diffracted radiation 460 is deflected by a sample product structure at a point that defines the center of the Ewald sphere 464. Two rays 460a and 460b of the diffracted radiation are scattered by the product structure, with respective angles θ relative to the specular ray 462. Each ray 460a, 460b passes through a point on the (notional) Ewald sphere impinges on a particular point in the (actual) U-V plane of detector 408, where it is detected by a corresponding pixel detector. Knowing the geometry of the apparatus within the inspection chamber, processor 410 is able to map pixel positions in an image captured by detector 408 to angular positions on the Ewald sphere 462. For convenience, the specular portion 462 of the reflected radiation is aligned with the horizontal direction in the diagram, and a direction normal to the plane of detector 408, but any coordinate system can be chosen. Thus a radial distance r on detector 408 can be mapped to an angle θ. A second angular coordinate y represents deflection out of the plane of the diagram, and can be mapped also from the position on the detector. Only rays with φ=0 are shown in this illustration, corresponding to pixels on a line 466 on the detector.

Returning to FIG. 4, pixel data 466 is transferred from detector 408 to processor 410. Using lensless imaging, a 3-D image (model) of the target can be reconstructed from the diffraction pattern captured on the image detector. From the reconstructed image, measurements of deviations such as overlay and CD are calculated by processor 410 and delivered to the operator and control systems of the lithographic manufacturing facility. Note that the processor 410 could in principle be remote from the optical hardware and inspection chamber. Functions of the processor could be divided between local and remote processing units, without departing from the principles disclosed herein. For example, a local processor may control the apparatus to capture images from one or more product structures on one or more substrates, while a remote processor processes the pixel data to obtain measurements of the structure. The same processor or yet another processor could form part of the supervisory control system SCS or lithographic apparatus controller LACU and use the measurements to improve performance on future substrates.

A particular example of lensless imaging is known as ankylography, which offers the potential to determine properties of a 3-D structure from a single capture. In order to do this, an image of a radiation field is obtained, that has been diffracted by an object, for example a microstructure made by lithography. Different types of prior information are considered in the literature, which allow phase information to be retrieved, so that the object can be reconstructed, even though the radiation field is only captured in intensity (revealing the magnitude but not the phase of the radiation field).

In the paper “Designing and using prior data in Ankylography: Recovering a 3D object from a single diffraction intensity pattern” E. Osherovich et al http://arxiv.org/abs/1203.4757, molecules are reconstructed from an image of a space of 128×128×128 voxels. (A voxel is the smallest element of a 3-dimensional image (model), that is, the volume equivalent of a pixel in a 2-dimensional image.) Prior knowledge is introduced by modifying the sample by drilling tiny holes at known positions nearby the sample.

In his PhD thesis “Numerical methods for phase retrieval” the author Osherovich discloses other types of prior knowledge that may be applied to assist phase retrieval (Technion, Israel—Computer Science Department—Ph.D. Thesis PHD-2012-04-2012). These other types of prior knowledge include, for example, information that the object is located at a restricted set of locations within an otherwise sparse image field, and information derived from a blurred image of the same object captured by a microscope.

Other approaches are described by K S Raines et al in a Letter “Ankylography: Three-Dimensional Structure Determination from a Single View”, published in Nature 463, 214-217 (14 Jan. 2010), doi:10.1038/nature08705. The same work is described in a slideshow by Jianwei (John) Miao, KITP Conference on X-ray Science in the 21st Century, UCSB, 2-6 Aug. 2010, available at http://online.kitp.ucsb.edu/online/atomixrays-c10/miao/.

The described techniques use radiations of wavelength comparable with the smallest features made by modern semiconductor lithographic technique, the inventor has considered whether the techniques of lensless imaging, including for example ankylography and ptychography , might be applied to measure properties of device structures, which are challenging to measure by visible light scatterometry. Unfortunately, the types of constraints (prior knowledge) exploited in the literature cannot readily be applied to the device structures of interest. A semiconductor memory device is not an isolated structure in an otherwise sparse environment. It is not practical to drill small holes in such a product, not only because to do so would destroy the functional device, but because a measurement technique is wanted that can be performed in a fraction of a second during high volume manufacture.

The inventor has determined that coherent diffraction imaging can be applied to the inspection of complex, extensive device structures, using a different type of prior knowledge in a different way. In embodiments of the present invention, prior knowledge of a nominal structure is used, representing for example the device structure as designed. Using this prior knowledge together with the observed diffracted radiation, CDI is then performed to reconstruct deviations from the nominal structure. Where the nominal structure is for example the device structure ‘as designed’, the reconstructed deviations can represent directly parameters of interest, such as CD error and overlay.

FIG. 6 illustrates steps in the production of a layer in a product structure 500 using a multiple patterning process. The structure comprises lengths of conductors, such as may be formed in one layer within the logic area 304 shown in FIG. 3. In step (a) a periodic grid of conductors 502, 504, 506, 508 is formed by using a grid mask 510 in a lithographic step 512 and followed by a self-aligned pitch-multiplying process 514. At (b) a first cut mask 520 is used in a second lithographic step 522 followed by an etching step 524. Cuts 526, 528, 530 are made at specific locations in the conductors 502, 506, 508, as shown, separating them into separate conductors 502a, 502b and so forth. At (c) a second cut mask 540 is used in a third lithographic step 542 followed by an etching step 544. Cuts 546, 544 are made at specific locations in the conductors 504, 506 as shown, separating them into separate conductors 504a, 504b and so forth.

At 500 in step (c) the finished pattern of conductors is shown, as it would be produced if the lithographic steps 512, 522, 542 are performed with perfect alignment and perfect imaging, and the etching and other steps 514, 524, 544 are also performed perfectly. Of course, as already mentioned, a real product structure produced by these steps may deviate from the form shown at 500. FIG. 6 (d) shows such a real product structure 500′. Conductors 502a′ and 502b′ in the real structure are somewhat thinner than in the nominal structure, indicated by CD error ΔCD. Cuts 526′, 528′ and 530′ in the real product structure are displaced to the right relative to their position in the nominal product structure, indicated by overlay error Δx. Cuts 546′ and 548′ in the real product structure are displaced somewhat upward, indicated by overlay error Δy.

Of course, these are not the only errors that may be present in a real product structure. Moreover, the magnitudes of these errors may vary across the substrate, and may vary within each field. Measurement of these errors on the real product structure at several fields across the substrate and at several points within fields is therefore desired to obtain data for quality control and process improvement.

It will be seen that the product structure 500, although based on a periodic grid in this example, is not periodic at the end of the process. The product structure seen by the metrology apparatus may comprise hundreds of grid lines and thousands of cuts. Existing reconstruction methods used in metrology of such structures are designed to exploit periodicity in the structure, as seen in the DRAM cell area 306. Existing reconstruction methods are not adapted to measure CD and overlay errors in non-periodic structures like those shown at 306 and 500.

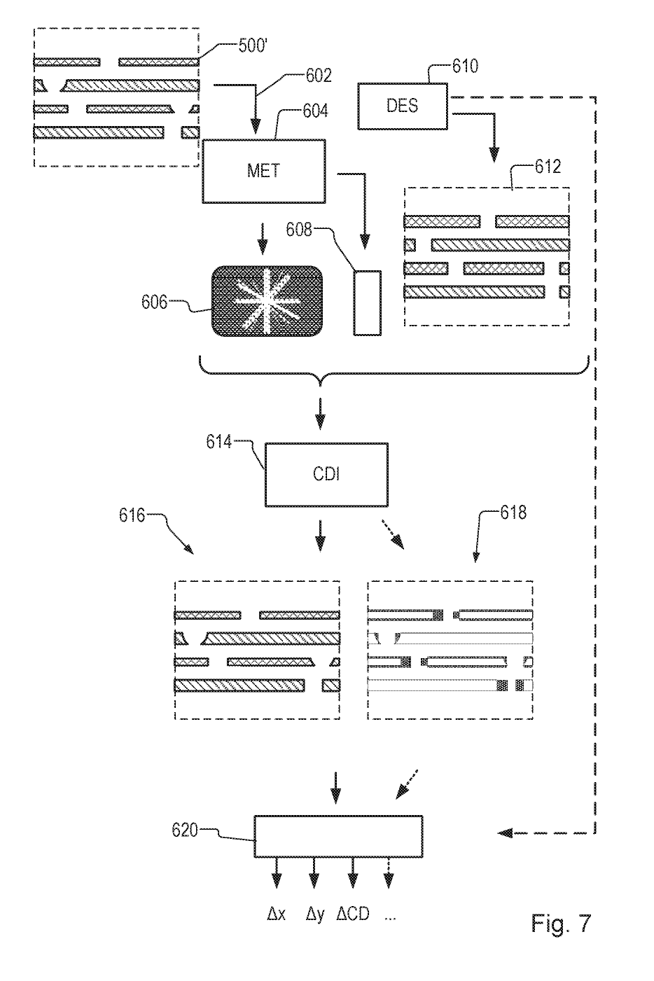

FIG. 7 illustrates the complete measurement process using the apparatus of FIG. 4 to measure properties of the product structure 500′ shown in FIG. 3. The process is implemented by operation of the hardware illustrated in the drawings, in conjunction with processor 410 operating under control of suitable software (program instructions). As mentioned above functions of (i) controlling the operations of the hardware and (ii) processing the image data 466 may be performed in the same processor, or may be divided between different dedicated processors. Processing of the image data need not even be performed in the same apparatus or even in the same country.

At 602 a product structure 500′ is presented to the radiation spot S in inspection chamber 440, using actuators of substrate support 406. This is for example the product structure 500′ illustrated in FIG. 6, which may be a small area within logic area 304 of the product illustrated in FIG. 3. Radiation source 402 and detector 408 are operated one or more times at 604 to capture at least one intensity distribution image 606s6. Where ankylography is being used, a single image may be sufficient. Using ptychography, two or more images may be captured, with shifted but overlapping spots S. Where the radiation source produces thousands of pulses per second of EUV radiation, a single captured image may for example accumulate photons from many pulses. Also received is auxiliary data (metadata) 608 defining operating parameters of the apparatus associated with each image, for example the illumination wavelength, polarization and the like. This metadata may be received with each image, or defined and stored in advance for a set of images.

Also received or previously stored is reference data from a database 610. In the present example, reference data 612 represents at least some features of the nominal structure 500 to which the real device structure 500′ is supposed to conform. The reference data may for example comprise a parameterized description of the nominal structure. It may for example comprise the path, line width, line height of every feature in a layer. It may comprise a parameterized description of more than one layer.

From the received image data 606, the metadata 608 and the reference data 612, processor PU performs coherent diffractive imaging calculations at 614. These include for example iterative simulations of interaction between radiation and a structure, using the knowledge of the nominal product structure to constrain the simulations. Using this prior knowledge, phase retrieval can be achieved, even though the captured image is only an intensity of the diffraction pattern. The calculations at step 614 can be performed for example to calculate a synthetic 3-dimentional image 616 of the real product structure as it would be seen if focused by real imaging optical system onto an image sensor. Alternatively or in addition, the calculation may be performed to deliver a 3-dimensional difference or “delta” image 618 representing the differences between the nominal product structure represented at 612 and the real product structure 306′.

Detailed implementation of the step 614 can be based on the techniques of lensless imaging disclosed in the references above, adapted to use the reference data 612 as prior knowledge. Although the representations of these images 616 and 618 are two-dimensional in the present drawings, it will be understood that the method can produce three-dimensional images, so that the features in different layers of the product structure can be resolved. Although the representations show all the features of the product structure in the same image, it would be an option for other calculation to deliver each set of features in a separate image, for example using the prior knowledge to extract an image of only the bit line contacts.

At 620 calculations are made to deliver whatever parameters are of interest: overlay of different features relative to other features in X and/Y directions, CD of certain features, CD uniformity, line edge roughness and so on. Purely by way of example, the parameters Ax, Ay and ACD are shown as outputs in FIG. 7. The calculation of performance parameters can also use information from the design database 610 and the metrology recipe 608.

The illustrated process is repeated for all structures of interest. Note that the computational parts of the process can be separated in time and space from the image capture. The computations do not need to be completed in real time, although of course that would be desirable. Only the capturing of the image at 604 requires the presence of the substrate, and so only that step impacts productivity throughput of the lithographic manufacturing process overall.

A method of manufacturing devices using the lithographic process can be improved by providing an inspection apparatus as disclosed herein, using it to measure processed substrates to measure parameters of performance of the lithographic process, and adjusting parameters of the process to improve or maintain performance of the lithographic process for the processing of subsequent substrates.

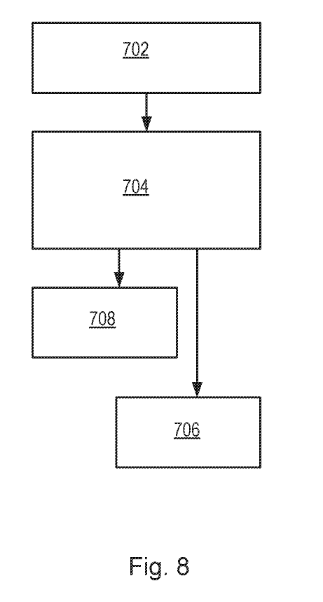

FIG. 8 illustrates a general method of controlling a lithographic manufacturing facility such as the one shown in FIGS. 1 and 2, using the lensless imaging methods described above. At 702, a substrate is processed in the facility to produce one or more product structures 306′ on a substrate such as a semiconductor wafer. The structures may be distributed at different locations across the wafer. The structures may be parts of functional devices, or they may be dedicated metrology targets. At 704 the method of FIG. 5 is used to measure properties of the structures at locations across the wafer. At 706 recipes for controlling the lithographic apparatus and/or other processing apparatuses are updated based on the measurements reported in step 704. For example, the updates may be designed to correct deviations from ideal performance, identified by the lensless imaging. Performance parameters may be any parameter of interest. Typical parameters of interest might be, for example, linewidth (CD), overlay, CD uniformity and the like. At 708, optionally, the recipe for performing the measurement on future substrates may be revised based on findings in step 704 or from elsewhere.

By the techniques disclosed herein, imaging can be performed on real product structures instead of metrology targets specifically designed and formed for the purposes of measurement. Using prior knowledge of the nominal structure reduces constraints on the resolution requirements and the 3-D resolution capabilities of the physical imaging hardware. It also circumvents the lack of prior knowledge such as sparseness or drilled holes. Moreover, using prior knowledge is also expected to reduce the number of photons needed for an accurate imaging. This helps to reduce the acquisition time and so aid high-volume measurement in high-volume manufacturing context.

In association with the optical system hardware, an embodiment may include a computer program containing one or more sequences of machine-readable instructions defining methods of calculating synthetic images and/or controlling the inspection apparatus 400 to implement the illumination modes and other aspects of those metrology recipes. This computer program may be executed for example in a separate computer system employed for the image calculation/control process. Alternatively, the calculation steps may be wholly or partly performed within unit PU in the apparatus of FIG. 4 and/or the control unit LACU of FIGS. 1 and 2. There may also be provided a data storage medium (e.g., semiconductor memory, magnetic or optical disk) having such a computer program stored therein.

Although specific reference may have been made above to the use of embodiments of the invention in the context of optical lithography, it will be appreciated that the invention may be used in other applications, for example imprint lithography. In imprint lithography, topography in a patterning device defines the pattern created on a substrate. The topography of the patterning device may be pressed into a layer of resist supplied to the substrate whereupon the resist is cured by applying electromagnetic radiation, heat, pressure or a combination thereof The patterning device is moved out of the resist leaving a pattern in it after the resist is cured.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. An inspection apparatus for measuring properties of a product structure, the apparatus comprising:
a radiation source;
an illumination optical system; and
an image detector in combination with the illumination optical system,
wherein the radiation source and the illumination optical system are arranged to provide a spot of radiation on the product structure, the radiation having a wavelength less than 50 nm,
wherein the image detector is arranged to capture at least one diffraction pattern formed by said radiation after scattering by the product structure, and
wherein the inspection apparatus further comprises a processor arranged (i) to receive image data representing said captured diffraction pattern, (ii) to receive reference data describing assumed structural features of the product structure and (iii) to calculate from the image data and the reference data one or more properties of the product structure.

2. The inspection apparatus as claimed in claim 1, wherein said reference data specifies a plurality of sets of features present in a plurality of layers of the product structure.

3. The inspection apparatus as claimed in claim 1, wherein said reference data specifies nominal dimensions of one or more features in the product structure.

4. The inspection apparatus as claimed in claim 1, wherein the calculated properties include a linewidth of features in one or more arrays of features forming the product structure.

5. The inspection apparatus as claimed in claim 1, wherein the calculated properties include a positional deviation between a feature of the product structure and a corresponding feature in the nominal structure.

6. The inspection apparatus as claimed in claim 1, wherein said calculated properties include an overlay error between features in a first pattern and features in a second pattern in the product structure.

7. The inspection apparatus as claimed in claim 1, wherein said radiation source comprises a higher harmonic generator and a pump laser.

8. The inspection apparatus as claimed in claim 1, including a wavelength selector for selecting a wavelength of said radiation.

9. The inspection apparatus as claimed in claim 1, wherein the radiation source and the illumination optical system are arranged to provide the radiation having a wavelength in the range 1 nm to 20 nm.

10. The inspection apparatus as claimed in claim 1, wherein said illumination optical system is operable to deliver said spot of radiation with a diameter less than 15 μm.

11. A method of measuring properties of a product structure, the method comprising the steps:
providing a spot of radiation on the product structure, the radiation having a wavelength less than 50 nm;
capturing at least one diffraction pattern formed by said radiation after scattering by the product structure;
receiving reference data describing assumed structural features of the product structure; and
calculating from the image data and the reference data one or more properties of the product structure.

12. The method as claimed in claim 11, wherein said reference data specifies a plurality of sets of features present in a plurality of layers of the product structure.

13. The method claimed in claim 11, wherein said reference data specifies nominal dimensions of one or more features in the product structure.

14. The method as claimed in claim 11, wherein the calculated properties include a linewidth of features in one or more arrays of features forming the product structure.

15. The method as claimed in claim 11, wherein the calculated properties include a positional deviation between a feature of the product structure and a corresponding feature in the nominal structure.

16. The method as claimed in claim 11, wherein said calculated properties include an overlay error between features in a first pattern and features in a second pattern in the product structure.

17. The method as claimed in claim 11 wherein said radiation is generated by a source comprising a higher harmonic generator and a pump laser.

18. The method as claimed in claim 11, including selecting a wavelength of the provided radiation from a range of wavelengths generated by the source.

19. The method as claimed in claim 11, wherein the provided radiation has a wavelength less than 20 nm.

20. The method as claimed in claim 11, wherein said spot of radiation has a diameter less than 15 μm.

21. A method of manufacturing devices, comprising
forming device features and metrology targets on a series of substrates by a lithographic process,
measuring properties of the metrology targets on one or more processed substrates using comprising:
providing a spot of radiation, the radiation having a wavelength less than 50 nm;
capturing at least one diffraction pattern formed by said radiation after scattering;
receiving reference data describing assumed structural features; and
calculating from the image data and the reference data the properties; and
adjusting parameters of the lithographic process for the processing of further substrates based on the measured properties.

22. A computer program product containing one or more sequences of machine-readable instructions for implementing method of measuring properties of a product structure, the method including operations comprising:
providing a spot of radiation on the product structure, the radiation having a wavelength less than 50 nm;
capturing at least one diffraction pattern formed by said radiation after scattering by the product structure;
receiving reference data describing assumed structural features of the product structure; and
calculating from the image data and the reference data one or more properties of the product structure.

23. (canceled)
